(19) United States
(12) Patent Application Publication
(10) Pub. No.: US 2016/0181290 A1
(43) Pub. Date: Jun. 23, 2016

(54) THIN FILM TRANSISTOR AND FABRICATING METHOD THEREOF, AND DISPLAY DEVICE

(71) Applicant: BOE Technology Group Co., Ltd., Beijing (CN)

(72) Inventor: Can WANG, Beijing (CN)

(73) Assignee: BOE TECHNOLOGY GROUP CO., LTD., Beijing (CN)

(21) Appl. No.: 14/435,825

(22) PCT Filed: Sep. 5, 2014
(86) PCT No.: PCT/CN2014/086079

§ 371 Date: Apr. 15, 2015

(30) Foreign Application Priority Data
Jun. 10, 2014 (CN) 201410256092.X

(51) Int. Cl. H01L 27/12; H01L 29/51; H01L 29/49; H01L 29/66

(52) U.S. Cl. CPC H01L 27/1225; H01L 29/66969; H01L 29/51; H01L 29/4908

(57) ABSTRACT

A thin film transistor and a fabricating method thereof, and a display device are disclosed according to embodiments of the present invention, which effectively reduce occurrences of hillocks on a surface of an aluminum film, increase stability of active layer property, and decrease power consumption of the products. The film transistor comprises: a substrate (10), and a gate electrode (12), a gate insulating layer (13), an active layer (14), a source electrode (15) and a drain electrode (16) sequentially formed over the substrate (10). The gate electrode (13) is formed between the substrate (10) and the gate insulating layer (13). The film transistor further comprises a first transition layer (11) disposed on the substrate and located between the gate electrode (12) and the substrate (10). The material of the first transition layer (11) has a coefficient of thermal expansion between the coefficients of thermal expansion of the materials for the substrate and the gate electrode. The gate insulating layer is formed at a temperature lower than a first limit temperature, which is referred as a temperature corresponding to a limit value of a film layer of the gate electrode (12) being not deformed under a compression stress.

### CROSS REFERENCE TO RELATED APPLICATIONS

This application is the National Stage of PCT/CN2014/086079 filed on Sep. 5, 2014, which claims priority under 35 U.S.C. §119 of Chinese Application No. 201410256091X filed on Jun. 10, 2014, the disclosure of which is incorporated by reference.

### FIELD

Embodiments of the present invention are related to a thin film transistor and a method of fabricating the film transistor, and a display device.

### BACKGROUND

A thin film transistor (TFT) is a field effect transistor which is widely used. In the display field, such as an Organic Light Emitting Diode (OLED), the TFT is configured to form a drive circuit to control a display signal to be applied to a separate pixel.

The TFT mainly comprises: an active layer, a gate electrode, a gate insulating layer, a source electrode and a drain electrode. At present, in the OLED, a layer of aluminum film (a metal aluminum or aluminum alloy film, referred as an aluminum film in general) is deposited on a substrate to form a gate electrode; then a silicon oxide layer is deposited over the gate electrode by a PECVD (Plasma Enhanced Chemical Vapor Deposition) method as a gate insulating layer. However, after the aluminum film forming the gate electrode is subjected to a process of depositing the gate insulating layer, hillocks easily occurred on a surface thereof, making it uneven, thus affecting the match between the gate insulating layer and the active layer to be formed subsequently, resulting in an adverse influence on the functionality of the TFT.

### SUMMARY

Embodiments of the present invention provide a TFT and a fabricating method of the TFT, and a display device. According to the embodiments of the present invention, the occurrence of hillocks may be efficiently reduced on the surface of the aluminum film, thereby increasing stability of the active layer, reducing power consumption of the products, and improving market competitiveness of the products.

In one aspect, the embodiments of the present invention provide a TFT. The TFT comprises: a substrate, and a gate electrode, a gate insulating layer, an active layer, a source electrode and a drain electrode sequentially formed over the substrate. The gate electrode is formed between the substrate and the gate insulating layer. The TFT further comprises: a first transition layer disposed on the substrate, and located between the gate electrode and the substrate. A material of the first transition layer has a coefficient of thermal expansion between a coefficient of thermal expansion of a material for the substrate and a coefficient of thermal expansion of a material for the gate electrode. And, the gate insulating layer is formed at a temperature lower than a first limit temperature. The first limit temperature is referred as a temperature corresponding to a limit value of a film layer of the gate electrode being not deformed under a compression stress.

In an example, the material of the gate electrode may be aluminum, the first limit temperature may be 150° C.

In an example, the substrate may be a glass substrate, the material of the first transition layer may be alumina.

In an example, the first transition layer may has a thickness of 50˜200 nm.

In an example, a material of the active layer may be a semiconductor oxide material.

In an example, a material of the gate insulating layer may be alumina.

Further, a second transition layer may be disposed between the active layer and the gate insulating layer. A material of the second transition layer may be an oxygen rich oxide of the material of the active layer.

In an example, the oxygen rich oxide has an oxygen content of 50%˜80% in mass percentage.

The embodiments of the present invention provide a display device comprising the TFT as described above.

In another aspect, the embodiments of the present invention provide a method of fabricating a thin film transistor (TFT). The method comprises steps of: forming a first transition layer on a substrate, a material of the first transition layer having a coefficient of thermal expansion of the material for the first transition layer is between a coefficient of thermal expansion of the a material for the substrate and a coefficient of thermal expansion of the material for the gate electrode; forming a pattern of a gate metal layer comprising a gate electrode on the first transition layer; forming a gate insulating layer on the gate electrode and the first transition layer at a temperature lower than a first limit temperature; and forming an active layer, a source electrode, and a drain electrode sequentially on the gate insulating layer.

In an example, the step of forming the pattern of the gate metal layer comprising the gate electrode may comprise forming an aluminum film on the first transition layer, and patterning the aluminum film to form the pattern of the gate metal layer comprising the gate electrode. The first limit temperature may be 150° C.,

In an example, the substrate may be a glass substrate. A material of the first transition layer may be alumina.

In an example, the step of forming the first transition layer on the substrate comprises forming a alumina film on the substrate by a sputtering method. The step of forming the aluminum film on the first transition layer comprises forming the aluminum film on the alumina film by a sputtering method.

In an example, a material of the active layer may be a semiconductor oxide material. Before forming the active layer, the method further comprises: forming a second transition layer on the gate insulating layer. The second transition layer may be formed of an oxygen rich oxide of the material of the active layer.

According to the TFT and its fabricating method, and the display device provided by the embodiments of the present invention, the first transition layer may be disposed between the gate electrode and substrate, the first transition layer has a coefficient of thermal expansion between a coefficient of thermal expansion of the material for the substrate and a coefficient of thermal expansion of the material for the gate electrode. And, the material of the gate insulating layer or film forming method are changed so that the material of the gate insulating layer have a film forming temperature lower than a limit value of the material of the gate electrode which is not deformed under a compression stress (if the material of the gate electrode is aluminum, a temperature corresponding to the limit value is between 100˜150° C. A specific value can be determined by testing in advance). Therefore it is possible to reduce a stress effectively in the gate electrode 12 due to a difference in the coefficient of thermal expansion between the substrate 10 and the film layer of the gate electrode 12 during a high temperature fabricating process to form the gate insulating layer, therefore, reducing occurrence of hillocks to some extent, increasing the stability of the active layer, reducing the power consumption of the product, and improving the market competitiveness of the product.

### BRIEF DESCRIPTION OF THE DRAWINGS

The technical solutions in the embodiments of the present invention will be described with reference to accompanying drawings. It is apparent that the drawings mentioned in the following description are only some embodiments of the present invention, and various other drawings can be obtained by those of ordinary skilled in the art without creative labor based on these drawings mention above.

FIG. 1 is a structure schematic view of a TFT according to a first embodiment of the present invention;

FIG. 2 is a structure schematic view of a TFT according to a second embodiment of the present invention;

FIG. 3 is a flow chart of a method of fabricating a TFT according to a third embodiment of the present invention; and

FIG. 4 is a structure view of an IPS array substrate according to a fourth embodiment of the present invention.

### DETAILED DESCRIPTION

The technical solution of the embodiments of the present disclosure will be described clearly and fully in connection with the drawings of the embodiments of the present disclosure. It is obvious that the described embodiments are just a part but not all of the embodiments of the present disclosure. Based on the described embodiments of the present disclosure, those skilled in the art can obtain all other embodiment without any inventive work, which all fall into the scope of the claimed invention.

Unless otherwise defined, technical terms or scientific terms used herein shall have a common meaning known by those skilled in the art of the present disclosure. Words and expressions such as “first”, “second” and the like used in the description and claims of the patent application of the present disclosure do not denote any sequence, quantity or importance, but distinguish different components. Likewise, words such as “a”, “an” and the like do not denote quantitative restrictions, but denote the presence of at least one. Words such as “connected”, “connecting” and the like are not restricted to physical or mechanical connections, but may include electrical connections, regardless of direct or indirect connections. Words such as “up”, “below”, “left”, “right”, etc., are only used to denote the relative positional relationship. Upon the absolute position of the described object changes, the relative positional relationship change correspondingly.

A TFT and a method of fabricating the TFT, and a display device are provided in according with embodiments of the present invention, which may efficiently reduce occurrence of hillocks on a surface of an aluminum film, increase stability of the active layer, reduce power consumption of the products, and improve market competitiveness of the products.

Hereinafter, technical solutions according to embodiments of the present invention will be described clearly and completely in connection with drawings in the embodiments of the present invention.

In a process of fabricating a TFT, a gate electrode is formed by depositing a layer of aluminum film (metal aluminum or aluminum alloy) on a substrate and then etching. Then a silicon oxide (or silicon nitride) layer is deposited over the gate electrode by a PECVD method as a gate insulating layer. The inventors of the present invention found that: film forming temperature by the PECVD method is high (generally, more than 300° C.), and when the aluminum film for forming the gate electrode is again subjected to a high temperature, hillocks are readily occurred on a surface of the aluminum film. The inventors of the present invention find following reasons for the occurrence of the hillocks. A substrate (generally a glass substrate) has a coefficient of thermal expansion less than that of the aluminum film as the gate electrode. In a high temperature process, thermal expansion of the aluminum film on a side adjacent to the substrate is limited. As the temperature rises, elastic deformation of the aluminum film is increased. Under a first limit temperature (about 100˜150° C. for pure aluminum film), a compression stress within the aluminum film reaches a limit. At this time, the compression stress will be released by an atom diffusion, thus forming hillocks on a surface of the film.

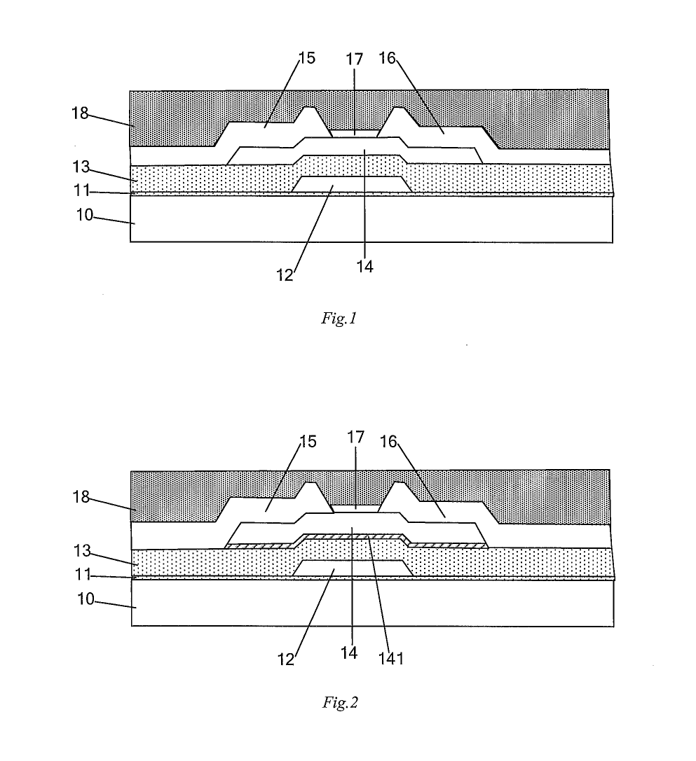

A first embodiment of the present invention provides a TFT. As illustrated in FIG. 1, the TFT comprises a substrate 10, and a gate electrode 12, a gate insulating layer 13, an active layer 14, a source electrode 15 and a drain electrode 16 sequentially formed over the substrate 10. The gate electrode 12 is formed over the substrate 10, the gate insulating layer 13 is formed between the gate electrode 12 and the substrate 10. The TFT according to the present embodiment further comprises a first transition layer 11 disposed on the substrate 10 and located between the gate electrode 12 and the substrate 10. A material of the first transition layer 11 has a coefficient of thermal expansion between a coefficient of thermal expansion of a material of the substrate 10 and a coefficient of thermal expansion of a material of the gate electrode 12; and, the gate insulating layer 13 is formed on the gate electrode 12 at a temperature lower than a first limit temperature. As mentioned above, the first limit temperature is referred as a temperature corresponding to a limit value of a film layer of the gate electrode 12 being not deformed under a compression stress. When the gate electrode 12 is subjected to a temperature greater than the first limit temperature, a film layer of the gate electrode 12 will release the compression stress by an atom diffusion, thus forming hillocks on the surface of the film of the gate electrode 12.

According to the TFT provided by the embodiments of the present invention, the first transition layer having the coefficient of thermal expansion between the coefficient of thermal expansion of the substrate and the coefficient of thermal expansion of the gate electrode is disposed between the gate electrode and the substrate, and the film forming temperature of the gate insulating layer is reduced, therefore the stress within the gate electrode due to the difference in the coefficients of thermal expansion between the substrate and the film layer of the gate electrode in the high temperature process for forming the gate insulation layer is reduced effectively, thus reducing the occurrence of hillocks in some extent, increasing performance of the active layer, reducing power consumption of the products, and increasing market competitiveness of the products.

In the above embodiment, the material of the gate electrode 12 is typically metal aluminum or aluminum alloy at present, also may be other metal or metal alloy. The substrate 10 is typically a glass substrate. The coefficients of thermal expansion of materials follow rules of: glass<oxide<metal<polymer. Thus the first transition layer 11 is formed of an oxide having a coefficient of thermal expansion between the glass and the metal. In a specific embodiment, the material of the substrate 10 is quartz glass, the material of the gate electrode 12 is a pure metal aluminum material, the material of the first transition layer 11 is alumina, the first transition layer has a thickness of 50˜200 nm. Aluminum has a coefficient of thermal expansion of 23.6×10⁻⁶/K, quartz glass has a coefficient of thermal expansion of 0.57×10⁻⁶/K; and alumina has a coefficient of thermal expansion of 8.8×10⁻⁶/K. The stress within the gate electrode due to the difference in the coefficients of thermal expansion between the substrate 10 and the film layer of the gate electrode 12 in the high temperature process for forming the gate insulation layer is reduced effectively, and both the pure aluminum film of the gate electrode 12 and the alumina film of the first transition layer can be formed in the same chamber by using a sputtering method, thus avoiding changing the fabricating equipment midway through the process, enabling simple process, low cost without necessity of additional investment.

If the material of the gate electrode 12 is pure aluminum, then the first limit temperature is about 100˜150° C. In the embodiments of the present invention, a specific value of the first limit temperature corresponding to the material of the gate electrode 12 can be determined by experiment or theoretical calculation based on the material of the gate electrode 12.

In this embodiment, the material of the active layer 14 is for example a semiconductor oxide including ZnO, IGZO, IZO, ZTO, and the like.

In comparison with the low temperature polysilicon (LTPS) TFT, the oxide TFT as mentioned above taking the semiconductor oxide as the material of the active layer has simpler fabricating process, lower fabricating cost and excellent uniformity across a large area due to the amorphous crystal structure mostly found in the film layer, thus the oxide TFT is suitable to meet the requirements of a new type display such as an active matrix OLED (AMOLED) with high definition, flexible display and the like especially adapting to a production line of a new generation. Further, the fabricating process of the oxide TFT has a good compatibility with the fabricating process of the amorphous silicon TFT (a-Si TFT), thus the oxide TFT can be fabricated on an a-Si TFT production line with technical modification. In this case, equipment investment can be saved by a large margin so as to reduce fabricating cost. However, as the oxide TFTs are used in mass production, a problem in stability of the active layer is prominent more and more. The semiconductor oxide device presents itself a threshold voltage Vth drift phenomenon in current-voltage property (IV property) during a longtime use under a high temperature or a low temperature. At present, the most plausible reason is that the semiconductor oxide active layer is in direct contact with the material of the gate insulating layer, resulting in a property mismatch. Therefore a problem of trap state of the semiconductor oxide to is more prominent, thus inducing accumulation of charges and a drift of IV property. To solve this problem, it is very important to select an appropriate gate insulating layer 13 and improve a contact at the interface between the gate insulating layer 13 and the active layer 14. In the present embodiment, alumina having a band gap width of 8.9 ev is selected as the gate insulating layer 13, which makes it difficult for the carriers in the active layer 14 to cross the potential barrier into the gate insulating layer 13, avoiding instability of the active layer 14. A good contact between the gate insulating layer 13 and the semiconductor oxide serving as the active layer 14 is achieved, which reduces defects in the interface between the gate insulating layer 13 and the active layer 14, and increases carrier mobility in the active layer 14.

Furthermore, the selection of the material of the gate insulating layer 13 needs to consider dielectric constant K of the gate insulating layer 13 in addition to matching the interface with the semiconductor oxide and avoiding hillock occurred in the process of forming the gate insulating layer 13.

A common material of the gate insulating layer is SiO₂. However, SiO₂ has a high film forming temperature by the PECVD method (>300° C.) to easily lead to a problem of generating hillocks on a pure aluminum film serving as the gate electrode on one hand, and SiO₂ has a low dielectric constant (the dielectric constant k of SiO₂≈3.9) so that with SiO₂ as a gate insulating film, the formed TFT has a low capacitivity and a high operating voltage, resulting in a large power consumption in the device on the other hand. In the present era of smart phones, due to the limitation of battery capacity, power consumption is an important factor to be considered. A way of reducing the power consumption is selecting a material with a high k value as the gate insulating layer to reduce the driving voltage, such as the high k value material of Al₂O₃, Y₂O₃, BaSrTiO, Ta₂O₅, and the like.

In the present embodiment, the material forming the gate insulating layer 13 preferably is alumina (Al₂O₃). On one hand, alumina has a high dielectric constant (k≈8.7), thus obtaining a low operating voltage and a high output current. And alumina has a good insulating property, allowing the TFT device to have a low drain current. On the other hand, alumina has a band gap of 8.9 eV, so that the carrier in the active layer 14 can not cross the potential barrier easily into the gate insulating layer 13, avoiding instability of the active layer 14, thus achieving good contact with the semiconductor oxide of the active layer 14, reducing the defect in the interface between the gate insulating layer 13 and the active layer 14, and increasing the carrier mobility. In the same time, the alumina film can be formed by a sputtering method due to a low film forming temperature, thereby hillocks can be avoided on the film layer of the gate electrode. In addition, the fabricating process is simple, the cost is low without additional investment.

FIG. 2 is a structural schematic view of a TFT according to embodiments of the present invention. As illustrated in FIG. 2, in order to further improve the interface contact between a gate insulating layer and a semiconductor oxide active layer, and reduce the property mismatch between the semiconductor oxide active layer and the gate insulating layer, the TFT according to the present embodiment further comprises a second transition layer 141 disposed between the active layer 14 and the gate insulating layer 13. A material of the second transition layer 141 is an oxygen rich oxide of the material of the active layer 14. In an example, before forming the active layer by depositing the semiconductor oxide, a film of the oxygen rich oxide is deposited. The oxygen rich oxide has an oxygen content of about 50%-80% in mass percentage. The film of the oxygen rich oxide is a substantially insulating film, which serves as a transition layer between the gate insulating layer and the semiconductor oxide material, thus improving the interface matching between the gate insulating layer and the active layer.

The TFT according to the present invention can suppress efficiently the occurrence of hillocks on the surface of the aluminum film, thereby increasing performance stability of the active layer, reducing power consumption of the product, and increasing market competitiveness of the product.

An embodiment of the present invention further provides a display device comprising the TFT as described above or the OLED back panel as described above. According to the display device of the present embodiment, performance stability of the active layer is improved, a drift phenomenon of the threshold voltage Vth is alleviated to some extent, display effect is enhanced, and a driving voltage of the display device is reduced, thus saving energy. The display device can be any products or parts with display function, such as a liquid crystal panel, an electronic paper, an OLED panel, a mobile telephone, a tablet computer, a TV set, a display, a notebook computer, a digital frame, a navigator and the like.

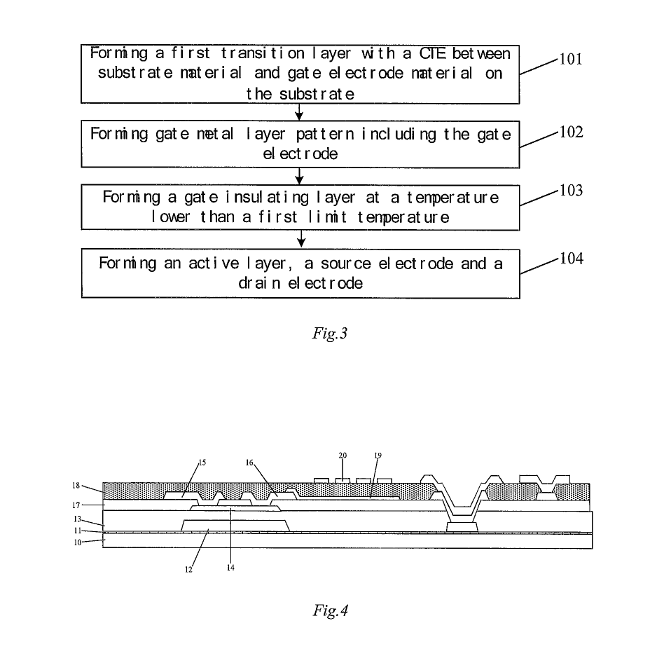

On the other hand, an embodiment of the present invention further provides a method of fabricating a TFT. As illustrated in FIG. 3, the method comprises following steps.

In Step 101, a first transition layer 11 is formed over a substrate 10. A material of the first transition layer 11 has a coefficient of thermal expansion between a coefficient of thermal expansion of a material for the substrate 10 and a coefficient of thermal expansion of a material for a gate electrode 12.

In Step 102, a pattern of a gate metal layer comprising the gate electrode 12 therein is formed on the first transition layer 11.

In Step 103, a gate insulating layer 13 is formed on the gate electrode 12 and first transition layer 11 under a condition with a temperature lower than a first limit temperature.

In Step 104, an active layer 14, a source electrode 15, and a drain electrode 16 are formed sequentially on the gate insulating layer 13.

In the method of fabricating the TFT according to the present invention, the first transition layer having a coefficient of thermal expansion between a coefficient of thermal expansion of the substrate and a coefficient of thermal expansion of the gate electrode is firstly deposited over the substrate, and a material of the gate insulating layer or film forming method thereof is changed so that the film forming temperature of the material of the gate insulating layer is lower than the first limit temperature corresponding to a limit value of the gate electrode material being not deformed under a compression stress. Therefore, it is possible to reduce efficiently hillocks to be formed on the film layer of the gate electrode, increase stability of the active layer, reduce power consumption of the product, and increase market competitiveness of the products.

Step 102 of forming the pattern of the gate metal layer comprising the gate electrode 12 therein comprises, for example, forming an aluminum film on the first transition layer 11, and forming the pattern of the gate metal layer comprising the gate electrode 12 therein by a patterning process. In the present embodiment, the material of the gate electrode 12 is aluminum with a corresponding first limit temperature of 150° C.

The substrate 10 in the embodiment is, for example, a glass substrate, the material of the first transition layer 11 is, for example, alumina. Step 101 of forming the first transition layer 11 on the substrate 10 comprises, for example, forming an alumina film on the substrate 10 by a sputtering method. Step 102 comprises, for example, forming an aluminum film on the alumina film by a sputtering method. The alumina film may be formed by a sputtering method due to a low film forming temperature, thus avoiding occurrence of hillocks on the film layer of the gate electrode, that is, the aluminum film. In this case, the process is simpler and the cost is low without additional investment.

The material of the active layer 14 is a semiconductor oxide, for example. Before forming the active layer 14, the method according to the embodiment of the present invention further comprises: forming a second transition layer 141 on the gate insulating layer 13. The material of the second transition layer 141 is an oxygen rich oxide of the material forming the active layer 14. For example, before depositing a semiconductor oxide for forming the active layer, the oxygen rich oxide film is deposited directly in the same chamber under an oxygen rich atmosphere. Then, the atmosphere inside the chamber is changed to deposit the semiconductor oxide film layer of the active layer. The oxygen rich oxide film has an oxygen content of about 50%-80% in mass percentage. The film is a substantially insulating film used as a transition layer between the gate insulating layer and the semiconductor oxide material, which improves interface matching effectively between the gate insulating layer and the oxide active layer.

In order to understand the method of forming the TFT according to the embodiments of the present invention more clearly for the skilled in the arts, various examples of the present invention are exemplified in the following to explain the fabricating methods according to the present invention in detail.

### FIRST EXAMPLE

In step 1, referring to FIG. 1, an alumina film serving as a first transition layer 11 is formed on a substrate 10. Oxygen gas (about 5%) is fed into a chamber for sputtering pure aluminum having a sputtering thickness of 50-200 Å. The film layer is used as the first transition layer 11 without being patterned.

In step 2, A pure aluminum gate electrode 12 is sputtered directly in the chamber for sputtering pure aluminum in situ (at a temperature of 100˜150° C.). No oxygen gas is fed into the sputtering chamber, which is re-evacuated to avoid oxidizing the pure aluminum. Then the film is patterned by a conventional method, and etched into a pattern of gate electrode comprising the gate electrode 12.

In step 3, an alumina film serving as a gate insulating layer 13 is sputtered at a low temperature. Argon (Ar) and oxygen (O₂) are fed into the chamber for sputtering pure aluminum with an oxygen concentration of about 5%, then an alumina film with a thickness of about 1000-2000 Å is formed by sputtering. Next, the gate insulating layer 13 is patterned with an etchant liquid.

In Step 4, a semiconductor oxide is deposited to form an active layer 14. The semiconductor oxide material can be IGZO, IZO, ZnO, ZTO, and the like.

In Step 5, an etching barrier layer 17, a source-grain metal layer comprising source/drain 15/16, and a passivation layer 18 is deposited sequentially by a conventional method.

### SECOND EXAMPLE

In Step 1, referring to FIG. 2, an alumina film is formed as a first transition layer 11 on a substrate 10. Oxygen gas (about 5%) is fed into a chamber for sputtering pure aluminum to perform reaction sputtering of pure aluminum with a sputtering thickness of 50-200 Å. The film layer is used as the first transition layer 11 without being patterned.

In Step 2, a pure aluminum gate electrode 12 is sputtered directly in the chamber for sputtering pure aluminum in situ (at a temperature of 100˜150° C.). No oxygen gas is fed into the sputtering chamber, which is re-evacuated to avoid oxidizing the pure aluminum. Then the film is patterned by a conventional method, and etched into a pattern of gate electrode comprising the gate electrode 12.

In Step 3, an alumina film as a gate insulating layer 13 is sputtered at a low temperature. Argon (Ar) and oxygen (O₂) are fed into the chamber for sputtering pure aluminum with an oxygen concentration of about 5%. An alumina film with a thickness of about 1000-2000 Å is formed by sputtering. Next, the gate insulating layer 13 is patterned using an etchant liquid.

In Step 4, a semiconductor oxide is deposited to form an active layer. The semiconductor oxide material may be GZO, IZO, ZnO, ZTO, and the like. In contrast to first example, in the second example, an oxygen rich oxide film is firstly deposited and then the semiconductor oxide film as an active layer 14 is directly deposited in situ. The oxygen content of the oxygen rich oxide film is about 50%˜80% in mass percentage. The oxygen rich oxide film is a substantially insulating film, which may act as a transition layer between a gate insulating layer material and a semiconductor oxide material, and effectively improve interface contact between the gate insulating layer and the oxide active layer.

In Step 5, an etching barrier layer 17, a source-grain metal layer comprising source/drain 15/16, and a passivation layer 18 are formed sequentially by a conventional method.

### THIRD EXAMPLE

In Step, as illustrated in FIG. 4, an alumina film serving as a first transition layer 11 is formed on a substrate 10. An oxygen gas (about 5%) is fed into a chamber for sputtering pure aluminum to perform reaction sputtering of pure aluminum with a sputtering thickness of 50-200 Å. The film layer is used as the first transition layer 11 without being patterned.

In Step 2, a pure aluminum gate electrode 12 is sputtered directly in the chamber for sputtering pure aluminum in situ (at a temperature of 100˜150° C.). No oxygen gas is fed into the sputtering chamber, which is re-evacuated to avoid oxidizing pure aluminum. Then the film is patterned by a conventional method, and etched into a pattern of gate electrode comprising the gate electrode 12.

In Step 3, an alumina film serving as a gate insulating layer 13 is sputtered at a low temperature. Argon (Ar) and oxygen (O₂) are fed into the chamber for sputtering pure aluminum with an oxygen concentration of about 5%. An alumina film is formed by sputtering to have a thickness of about 1000-2000 Å. Next, the gate insulating layer 13 is patterned using an etchant liquid.

In Step 4, a semiconductor oxide is deposited to form an active layer 14. The semiconductor oxide material may be GZO, IZO, ZnO, ZTO, and the like.

In Step 5, an etch barrier layer 17, a source-drain metal layer (comprising a source electrode 15 and a drain electrode 16), a first transparent conduct layer 19, a passivation layer 18, and a second transparent conduct layer 20 in a structure of an IPS (In-Plane Switching) type liquid crystal display device are formed by a conventional method.

### FOURTH EXAMPLE

The fourth example is substantially the same as the third example with following difference. In the fourth example, an oxygen rich oxide film is deposited, then a semiconductor oxide film serving as an active layer 14 is directly deposited in situ. The oxygen content of the oxygen rich oxide film is about 50%˜80% in mass percentage. The oxygen rich oxide film is a substantially insulating film, which may serve as a transition layer between a gate insulating layer material and a semiconductor oxide material, and may effectively improve interface contact between the gate insulating layer and the oxide active layer.

The fabricating method of the TFT according to embodiments of the present invention can effectively reduce occurrences of hillocks on a surface of a gate electrode film layer, increase stability of active layer property, decrease power consumption of the products, and increase market competitiveness of the products.

The foregoing detailed description of the invention has been presented for purposes of illustration and description. It is not intended to be exhaustive or to limit the invention to the precise form disclosed. Many modifications and variations are possible in light of the above teaching. The described embodiments were chosen in order to best explain the principles of the invention and its practical application to thereby enable the skilled in the art to best utilize the invention in various embodiments and with various modifications as are suited to the particular use contemplated. It is intended that the scope of the invention be defined by the claims appended hereto.

The present application claims the benefits of Chinese patent application No. 201410256092.X filed on Jun. 10, 2014, which is incorporated herein by reference in its entirety.

1: A thin film transistor (TFT) comprising a substrate, and a gate electrode, a gate insulating layer, an active layer, a source electrode and a drain electrode sequentially formed over the substrate,
wherein the gate electrode is formed between the substrate and the gate insulating layer,
the TFT further comprising:
a first transition layer disposed on the substrate, and located between the gate electrode and the substrate, a material of the first transition layer having a coefficient of thermal expansion between a coefficient of thermal expansion of a material of the substrate and a coefficient of thermal expansion of a material of the gate electrode; and
the gate insulating layer being formed at a temperature lower than a first limit temperature referred as a temperature corresponding to a limit value of a film layer of the gate electrode being not deformed under a compression stress.

2: The TFT according to claim 1, wherein the material of the gate electrode is aluminum, and the first limit temperature is 150° C.

3: The TFT according to claim 2, wherein the substrate is a glass substrate, the material of the first transition layer is alumina.

4: The TFT according to claim 3, wherein the first transition layer has a thickness of 50˜200 nm.

5: The TFT according to claim 1, wherein a material of the active layer is a semiconductor oxide material.

6: The TFT according to claim 5, wherein a material of the gate insulating layer is alumina.

7: The TFT according to claim 5, further comprising a second transition layer disposed between the active layer and the gate insulating layer, and a material of the second transition layer is an oxygen rich oxide of the material of the active layer.

8: The TFT according to claim 7, wherein
the oxygen rich oxide has an oxygen content of 50%˜80% in mass percentage.

9. (canceled)

10: A display device comprising a thin film transistor (TFT) comprising a substrate, and a gate electrode, a gate insulating layer, an active layer, a source electrode and a drain electrode sequentially formed over the substrate,
wherein the gate electrode is formed between the substrate and the gate insulating layer,
the TFT further comprising:
a first transition layer disposed on the substrate, and located between the gate electrode and the substrate, a material of the first transition layer having a coefficient of thermal expansion between a coefficient of thermal expansion of a material of the substrate and a coefficient of thermal expansion of a material of the gate electrode; and
the gate insulating layer being formed at a temperature lower than a first limit temperature referred as a temperature corresponding to a limit value of a film layer of the gate electrode being not deformed under a compression stress.

11: A method of fabricating a thin film transistor (TFT) comprising steps of:
forming a first transition layer on a substrate, a material of the first transition layer having a coefficient of thermal expansion of the material for the first transition layer is between a coefficient of thermal expansion of the a material for the substrate and a coefficient of thermal expansion of the material for the gate electrode;
forming a pattern of a gate metal layer comprising a gate electrode on the first transition layer;
forming a gate insulating layer on the gate electrode and the first transition layer at a temperature lower than a first limit temperature;
forming an active layer, a source electrode, and a drain electrode sequentially on the gate insulating layer.

12: The method according to claim 11, wherein the step of forming the pattern of the gate metal layer comprising the gate electrode comprises forming an aluminum film on the first transition layer, and patterning the aluminum film to form the pattern of the gate metal layer comprising the gate electrode; and
the first limit temperature is 150° C.

13: The method according to claim 12, wherein
the substrate is a glass substrate, the first transition layer is formed of a material of alumina.

14: The method according to claim 13, wherein the step of forming the first transition layer on the substrate comprises forming an alumina film on the substrate by a sputtering method;
the step of forming the aluminum film on the first transition layer comprises forming the aluminum film on the alumina film by a sputtering method.

15: The method according to claim 11, wherein a material of the active layer is semiconductor oxide; before forming the active layer, the method further comprising:
forming a second transition layer on the gate insulating layer, the second transition layer is formed of an oxygen rich oxide of the material of the active layer.

16: The display device according to claim 15, wherein the material of the gate electrode is aluminum, and the first limit temperature is 150° C.

17: The display device according to claim 16, wherein the substrate is a glass substrate, the material of the first transition layer is alumina.

18: The display device according to claim 17, wherein the first transition layer has a thickness of 50˜200 nm.

19: The display device according to claim 15, wherein a material of the active layer is a semiconductor oxide material.

20: The display device according to claim 19, wherein a material of the gate insulating layer is alumina.

21: The display device according to claim 19, further comprising a second transition layer disposed between the active layer and the gate insulating layer, and a material of the second transition layer is an oxygen rich oxide of the material of the active layer.
